(19) United States
(12) Patent Application Publication
(10) Pub. No.: US 2012/0280239 A1
(43) Pub. Date: Nov. 8, 2012

(54) THIN FILM TRANSISTOR ARRAY SUBSTRATE AND METHOD FOR FABRICATING THE THIN FILM TRANSISTOR ARRAY SUBSTRATE

(75) Inventors: Xiang LIU, Beijing (CN); Jianshe XUE, Beijing (CN)

(73) Assignee: BOE Technology Group Co., Ltd., Beijing (CN)

(21) Appl. No.: 13/464,094

(22) Filed: May 4, 2012

(30) Foreign Application Priority Data
May 6, 2011 (CN) 201110117665.7

(51) Int. Cl. H01L 33/08

(52) U.S. Cl. 257/59; 438/29; 257/E33.012

(57) ABSTRACT

The present disclosed technology is related to a TFT array substrate and a method for fabricating the TFT array substrate. The method may comprise: depositing a transparent conductive film layer and a source-drain metal layer in this order on a base substrate, and forming source electrodes, drain electrodes, data scan lines and transparent pixel electrodes by a first pattering process, with the transparent conductive film layer being left under the source electrodes, the drain electrodes and the data scan lines; on the resultant substrate, depositing a semiconductor layer and forming a patterned semiconductor layer by a second pattering process; and on the resultant substrate, depositing a gate insulator and a gate metal film in this order, and forming gate electrodes and gate scan lines by a third pattering process, the gate electrodes being located over the patterned semiconductor layer.

### BACKGROUND

Embodiments of the disclosed technology relate to a thin film transistor (TFT) array substrate and a method for fabricating the TFT array substrate.

In recent years, thin film transistor liquid crystal display (TFT-LCD) devices have been developed significantly due to the advantages of small size, low power consumption, low radiation, etc. The TFT-LCD devices have become prevailing in the current flat display device market, and have been applied widely, covering almost all the main kinds of electronic products in the information generation, such as LCD television, high-definition digital television, computer, mobile telephone, personal digital assistant (PDA), global position system (GPS), vehicle-loaded display, projection display, video camera, digital camera, electronic watch, calculator, electronic apparatus, instruments, public display and visional display, etc.

A TFT-LCD device generally comprises a liquid crystal display (LCD) panel, driving circuits and a backlight unit; the LCD panel is the main component affecting the display quality of the TFT-LCD. In general, the LCD panel is formed by injecting liquid crystal between two substrates and then attaching polarizing filters with their polarizing direction perpendicular to each other to the external sides of the two substrates. The upper one of the two substrates of the LCD panel functions as color filters (C/F), generally comprising tricolor filters of red (R) filters, green (G) filters and blue (B) filters so as to form the pixels. The color filter substrate is provided with transparent common electrodes. The lower substrate of the LCD panel is a TFT array substrate which is provided with thin film transistors arranged in a matrix and some peripheral circuits.

During fabricating a TFT-LCD, the red filters, the green filters, the blue filters and the light shielding layer are formed on C/F substrate, and then the TFT array substrate and the C/F substrate are attached together to face each other in a bonding process. Typically, a black matrix is formed on the C/F substrate of the TFT-LCD with an opaque material, for shielding light from light leakage regions. Generally, properties, yield and cost of a TFT-LCD are determined by the TFT array substrate and the fabricating process thereof. For the purpose of reducing cost and increasing yield of TFT-LCD, the fabricating process of the TFT-LCD array substrate has been simplified increasingly, from an initial 7-mask patterning process to a current 4-mask patterning process based on the slit photolithograph technology or a current 3-mask patterning process further in connection with a photoresist lifting-off technology.

At present, the 4-mask patterning process is adopted usually in fabricating of a TFT-LCD. As compared with the 4-mask patterning process, the 3-mask patterning process with a photoresist lifting-off technology in fabricating of the TFT-LCD is not applicable to the actual mass production due to low yield and high cost. Furthermore, in the conventional process for fabricating the TFT array substrate, a metal-oxide-semiconductor layer is formed firstly and then source and drain metal electrodes are formed thereon. Therefore, the metal-oxide-semiconductor layer may be damaged in formation of the source and drain metal electrodes, and the properties of the TFT-LCD may be affected adversely.

### SUMMARY

According to a first aspect of the present disclosed technology, a method for fabricating a thin film transistor (TFT) array substrate is provided. The method can comprise the steps of: (1) depositing a transparent conductive film layer and a source-drain metal layer in this order on a base substrate, and forming source electrodes, drain electrodes, data scan lines and transparent pixel electrodes by a first pattering process, with the transparent conductive film layer being left under the source electrodes, the drain electrodes and the data scan lines; (2) on the substrate obtained from the step (1), depositing a semiconductor layer and forming a patterned semiconductor layer by a second pattering process; and (3) on the substrate obtained from the step (2), depositing a gate insulator and a gate metal film in this order, and forming gate electrodes and gate scan lines by a third pattering process, the gate electrodes being located over the patterned semiconductor layer.

According to a second aspect of the present disclosed technology, a thin film transistor (TFT) array substrate is provided. The TFT array substrate can comprise: a base substrate; transparent pixel electrodes provided above the base substrate; source electrodes, drain electrodes and data scan lines with the transparent conductive film of the transparent pixel electrodes being left under them; a patterned semiconductor layer fainted on the source electrodes and the drain electrodes; a gate insulator covering the patterned semiconductor layer; and gate electrodes and gate scan lines formed on the gate insulator and located over the patterned semiconductor layer.

Further scope of applicability of the present disclosed technology will become apparent from the detailed description given hereinafter. However, it should be understood that the detailed description and specific examples, while indicating preferred embodiments of the disclosed technology, are given by way of illustration only, since various changes and modifications within the spirit and scope of the disclosed technology will become apparent to those skilled in the art from the following detailed description.

### BRIEF DESCRIPTION OF THE DRAWINGS

The disclosed technology will become more fully understood from the detailed description given hereinafter and the accompanying drawings which are given by way of illustration only, and thus are not limitative of the present disclosed technology and wherein:

FIG. 1 is a flow chart showing a method for fabricating a TFT array substrate according to an embodiment of the disclosed technology.

FIG. 2 is a plan view showing the substrate obtained from a step 1 according to a first embodiment of the disclosed technology.

FIG. 3 is a cross-sectional view, which is taken along a direction parallel to a gate line, showing the substrate obtained from the step 1 according to the first embodiment of the disclosed technology, that is, a cross-sectional view taken along a line A-A′ of FIG. 2.

FIG. 4 is a plan view showing the substrate obtained from a step 2 according to the first embodiment of the disclosed technology.

FIG. 5 is a cross-sectional view, which is taken along a direction parallel to a gate line, showing the substrate obtained from the step 2 according to the first embodiment of the disclosed technology, that is, a cross-sectional view taken along a line A-A′ of FIG. 4.

FIG. 6 is a plan view showing the substrate obtained from a step 3 according to the first embodiment of the disclosed technology.

FIG. 7 is a cross-sectional view, which is taken along a direction parallel to a gate line, showing the substrate obtained from the step 3 according to the first embodiment of the disclosed technology, that is, a cross-sectional view taken along a line A-A′ of FIG. 6.

FIG. 8 is a plan view showing the substrate obtained from a step 1 according to a second embodiment of the disclosed technology.

FIG. 9 is a cross-sectional view, which is taken along a direction parallel to a gate line, showing the substrate obtained from the step 1 according to the second embodiment of the disclosed technology, that is, a cross-sectional view taken along a line A-A′ of FIG. 8.

FIG. 10 is a plan view showing the substrate obtained from a step 2 according to the second embodiment of the disclosed technology.

FIG. 11 is a cross-sectional view, which is taken along a direction parallel to a gate line, showing the substrate obtained from the step 2 according to the second embodiment of the disclosed technology, that is, a cross-sectional view taken along a line A-A′ of FIG. 10.

FIG. 12 is a plan view showing the substrate obtained from a step 3 according to the second embodiment of the disclosed technology.

FIG. 13 is a cross-sectional view, which is taken along a direction parallel to a gate line, showing the substrate obtained from the step 3 according to the second embodiment of the disclosed technology, that is, a cross-sectional view taken along a line A-A′ of FIG. 12.

FIG. 14 is a plan view showing the substrate obtained from a step 4 according to the second embodiment of the disclosed technology.

FIG. 15 is a cross-sectional view, which is taken along a direction parallel to a gate line, showing the substrate obtained from the step 4 according to the second embodiment of the disclosed technology, that is, a cross-sectional view taken along a line A-A′ of FIG. 14.

FIG. 16 is a plan view showing the substrate obtained from a step 5 according to the second embodiment of the disclosed technology.

FIG. 17 is a cross-sectional view, which is taken along a direction parallel to a gate line, showing the substrate obtained from the step 5 according to the second embodiment of the disclosed technology, that is, a cross-sectional view taken along a line A-A′ of FIG. 16.

### DETAILED DESCRIPTION

Hereinafter, one or more embodiments of the disclosed technology will be described in detail with reference to the accompanying drawings so that the objects, technical solutions and advantages of the embodiments of the disclosed technology will become more apparent. It should be noted that the embodiments described below are merely a portion of but not all of the embodiments of the disclosed technology, and thus various modifications, combinations and alterations may be made on basis of the described embodiments without departing from the spirit and scope of the disclosed technology.

The embodiments of the disclosed technology are made so that during fabricating a thin film transistor (TFT) array substrate, for the pixels, source and drain electrodes are formed firstly and then a semiconductor layer is formed so as to prevent the semiconductor layer from being damaged in forming of the source and drain electrodes and prevent the properties of the TFT-LCD from being adversely affected.

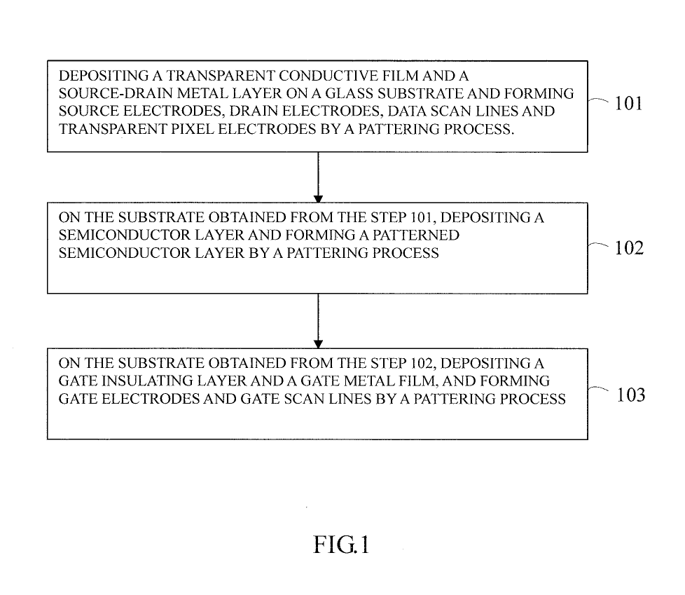

A method for fabricating a TFT array substrate is provided in an embodiment of the disclosed technology. FIG. 1 is a flow chart showing the method for fabricating the TFT array substrate according to the embodiment of the disclosed technology. As shown in FIG. 1, the method for fabricating the TFT array substrate in this embodiment may comprise mainly the following steps:

Step 101, depositing a transparent conductive film layer and a source-drain metal layer in this order on a base substrate (e.g. a glass substrate), and forming source electrodes, drain electrodes, data scan lines and transparent pixel electrodes by a first pattering process, with the transparent conductive film layer being left under the source electrodes, the drain electrodes and the data scan lines;

Step 102, depositing a semiconductor layer on the substrate obtained from the step 101, and forming a patterned semiconductor layer above the source electrodes and the drain electrodes by a second pattering process;

Step 103, depositing a gate insulator and a gate metal film in this order on the substrate obtained from the step 102, and forming gate electrodes and gate scan lines by a third pattering process, wherein the gate electrodes are located over the patterned semiconductor layer. So far the fabricating of the TFT array substrate is completed.

In the embodiment of the disclosed technology, the patterning processes may comprise, for example, photoresist-coating, exposing, developing, etching, lifting-off, etc.

In addition, before depositing the transparent conductive film layer and the source-drain metal layer in this order on the base substrate, the method for fabricating the TFT array substrate in the embodiment of the disclosed technology can further comprise: depositing a protective layer on the base substrate.

Furthermore, before depositing the transparent conductive film layer and the source-drain metal layer in this order on the base substrate, the method for fabricating the TFT array substrate in the embodiment of the disclosed technology may further comprise: forming a black matrix and forming a variety of color filters such as Red (R) filters, Blue (B) filters and Green (G) filters on the base substrate.

Still after forming the black matrix and forming the R filters, the B filters and the G filters on the base substrate, but before depositing the transparent conductive film layer and the source-drain metal layer in this order on the base substrate, the method for fabricating the TFT array substrate in the embodiment of the disclosed technology may further comprise: coating an organic flattening layer on the base substrate, and then forming the protective layer on the organic flattening layer, followed by depositing the transparent conductive film layer and the source-drain metal layer and forming the source electrodes, the drain electrodes, the data scan lines and the transparent pixel electrodes by the pattering process. In the method for fabricating the TFT array substrate according to the embodiment of the disclosed technology, for example, three patterning processes can be performed to form the R filters, the B filters and the G filters, respectively.

In the embodiment of the disclosed technology, the depositing of the gate insulator may comprise: depositing two gate insulating sub-layers successively by using plasma enhanced chemical vapor deposition (PECVD); one of the sub-layers which contacts the semiconductor layer is deposited at a lower speed, while the other layer is deposited at a higher speed.

In the embodiment of the disclosed technology, the forming of the source electrodes, the drain electrodes, the data scan lines and the transparent pixel electrodes by the first pattering process may comprise: forming the source electrodes, the drain electrodes, the data scan lines and the transparent pixel electrodes by exposing photoresist with a gray tone or half tone mask (or reticle), developing and several etching processes.

A TFT array substrate is provided in another embodiment of the disclosed technology. The array substrate may comprises: a base substrate (e.g. a glass substrate or a plastic substrate); a transparent pixel electrode provided on the base substrate; source electrodes, drain electrodes and data scan lines, with the transparent conductive film for forming the transparent pixel electrode being left under the source electrodes, the drain electrodes and the data scan lines; a patterned semiconductor layer formed above the source electrodes and the drain electrodes; a gate insulator covering the patterning semiconductor layer; and gate electrodes and gate scan lines formed on the gate insulator and located over the patterned semiconductor layer.

In the embodiment of the disclosed technology, the array substrate can also comprise a protective layer which is deposited on the base substrate before forming the source electrodes, the drain electrodes, the data scan lines and the transparent pixel electrodes.

In another embodiment of the disclosed technology, the array substrate may further comprise a black matrix and a variety of color filters, e.g., R filters, B filters and G filters. Before forming the source electrodes, the drain electrodes, the data scan lines and the transparent pixel electrodes, the black matrix is formed on the base substrate and then the R filters, the B filters and the G filters are formed respectively.

In further another embodiment of the disclosed technology, the array substrate may comprise an organic flattening layer and a protective layer. Before forming the black matrix and the R filters, the B filters and the G filters, the organic flattening layer is coated on the base substrate, and then the protective layer is for example deposited on the organic flattening layer.

In one embodiment of the disclosed technology, the source electrodes, the drain electrodes, the data scan lines and the transparent pixel electrodes are formed by exposing with a gray tone or half tone mask, developing and several etching processes.

### First Embodiment

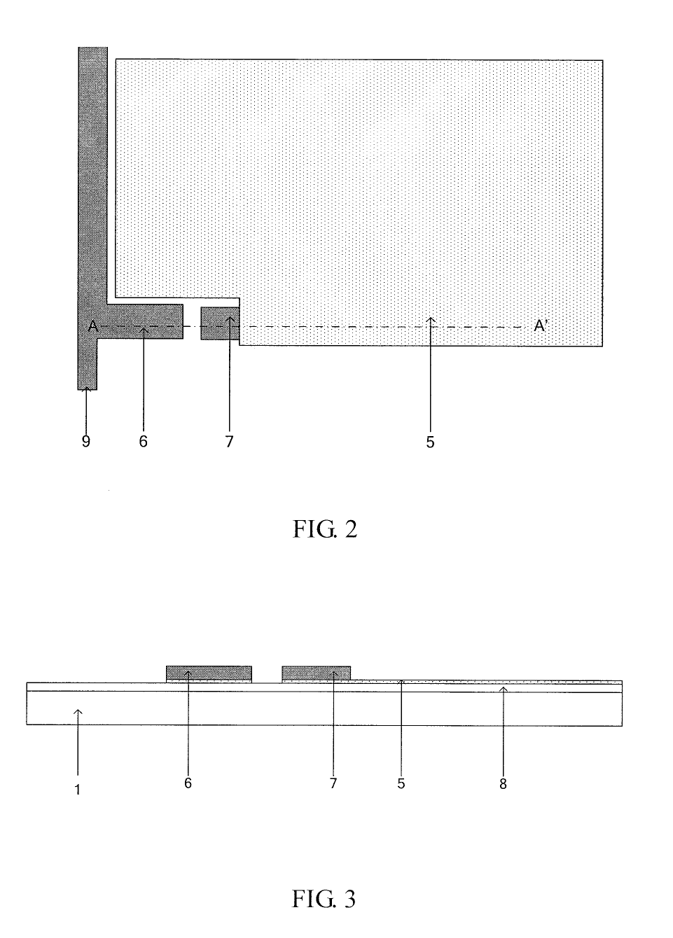

The first embodiment of the disclosed technology will be described with reference to FIGS. 2 to 7 below. In this embodiment, a method for fabricating an active driving TFT array substrate is provided, which can comprise the following steps.

Step 1. Firstly, a protective layer 8 is deposited on a glass substrate 1 with a thickness of 500 to 2000 Å by using a PECVD method. Next, a transparent conductive film with a thickness of about 300 to 1500 Å and a source-drain metal layer with a thickness of about 2000 to 3000 Å are sequentially deposited by using a sputtering or thermal evaporation method. After exposing with a gray tone or half tone mask, developing and several etching processes (first patterning process) are performed, source electrodes 6, drain electrodes 7, data scan lines 9 and transparent pixel electrodes 5 are formed, and the plan view and the cross-sectional view of one pixel are shown in FIGS. 2 and 3, respectively.

For example, oxide, nitride or oxide nitride can be selected to form the protective layer 8, and the corresponding reactive gas can be selected from a mixture of SiH₄, NH₃ and N₂ or a mixture of SiH₂Cl₂, NH₃ and N₂. Since the protective layer 8 is an inorganic insulating layer, it is possible to provide a better protection to the metal-oxide-semiconductor layer to be formed later and improve the stability of the metal-oxide-semiconductor layer.

Generally, the transparent pixel electrode 5 is made of nano indium tin oxide (ITO) or the other metal and metal oxide. The source electrodes 6 and the drain electrodes 7 can be made of a material selected from a group consisting of Cr, W, Ti, Ta, Mo, Al, Cu and any alloy thereof, in a form of single layer or multilayer structure.

Before performing this step, that is, before depositing the transparent conductive film, a protective layer can be deposited on the glass substrate in advance. The protective layer can protect the TFT channel to prevent the TFT channel from contacting with the glass substrate directly, which results in a poor interface.

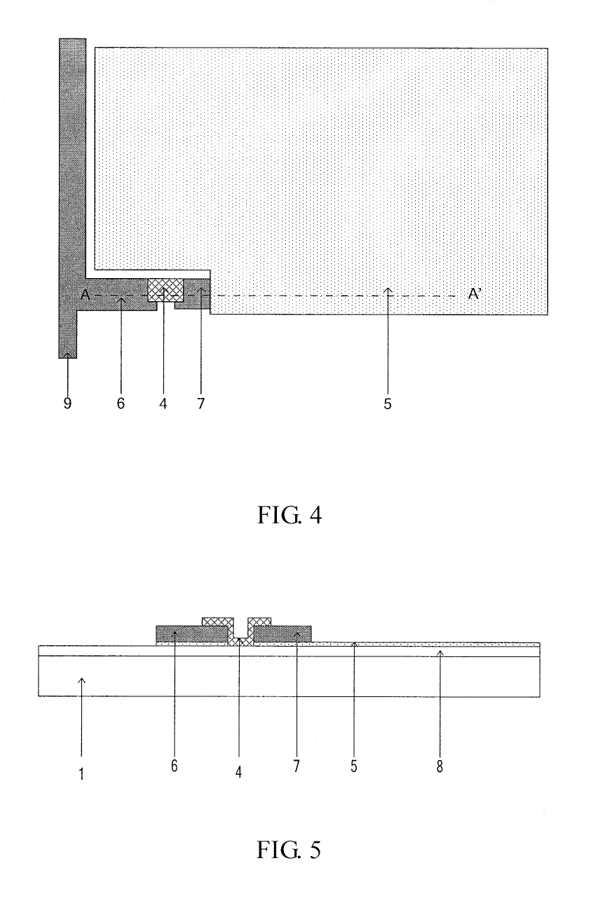

Step 2. On the substrate obtained from the step 1, a semiconductor layer with a thickness of about 100 to 4000 Å is deposited between the source electrodes 6 and the drain electrodes 7 and above them. Then, a patterned semiconductor layer 4 is formed by a patterning process (the second patterning process) on the semiconductor layer, and the plan view and the cross-sectional view of one pixel are shown in FIGS. 4 and 5, respectively.

For example, the semiconductor layer 4 can be made of amorphous IGZO or other metal oxide semiconductors.

In this step, since the patterned semiconductor layer is formed by the second patterning process, it is possible to make the patterned semiconductor layer finely and prevent it from being damaged. The semiconductor layer can be made of a metal oxide semiconductor material, such as IGZO, having a wide gap, which leads to substantially no light leakage current generated when the semiconductor layer is irradiated by any visible light. Therefore, there is no need to use a light-shielding layer in the later fabricating process, which can simplify the fabricating process and reduce the cost.

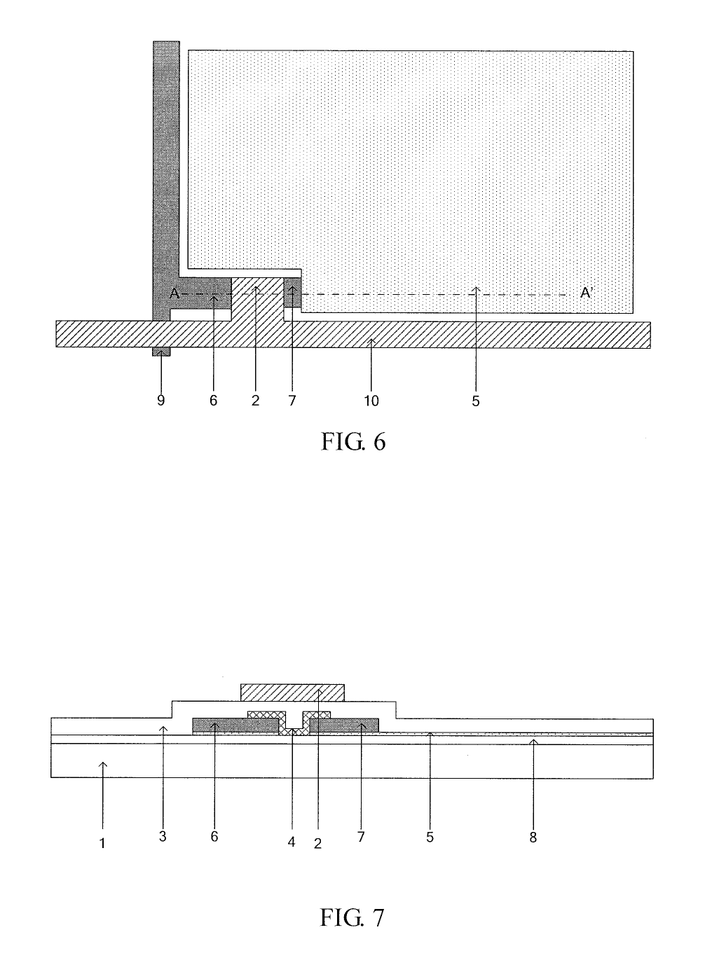

Step 3. On the substrate obtained from the step 2, a gate insulator 3 with a thickness of 1000 to 4000 Å is deposited successively by using a PECVD method, then a gate metal film with a thickness of 4000 to 15000 Å is deposited, and finally gate electrodes 2 and gate scan lines 10 are formed by a patterning process (the third patterning process). So far the fabricating of the TFT array substrate is completed, and the plan view and the cross-sectional view of one pixel are shown in FIGS. 6 and 7, respectively.

For example, a sputtering or thermal evaporation method can be adopted for depositing the gate metal film. The gate metal film can be made of a material selected from a group consisting of Cr, W, Cu, Ti, Ta, Mo and any alloy thereof, in form of a single layer or multilayer structure.

For example, oxide, nitride or oxide nitride can be selected to form the gate insulator 3, and the corresponding reactive gas can be selected from a mixture of SiH₄, and N₂ or a mixture of SiH₂Cl₂, NH₃ and N₂. Here, the gate insulator 3 can be in form of a single layer or dual layer structure. When the gate insulator 3 comprises two sub-layers, one of the sub-layers which contacts the semiconductor layer is deposited at a lower speed than that of the other sub-layer. In this manner, it is possible to form a better interface between the gate insulator 3 and the semiconductor layer, which can improve properties of the TFT and improve the production efficiency.

In this embodiment, the source electrodes, the drain electrodes and the transparent pixel electrode are formed by the first patterning process so as to prevent the semiconductor layer from being damaged in forming of the source and drain electrodes and the transparent pixel electrodes after the semiconductor layer has been formed. Furthermore, the fabricating of the whole TFT array substrate can be completed by using three pattering processes, without incorporating the photoresist lifting-off technology, while the process is simple and the yield can be high.

### Second Embodiment

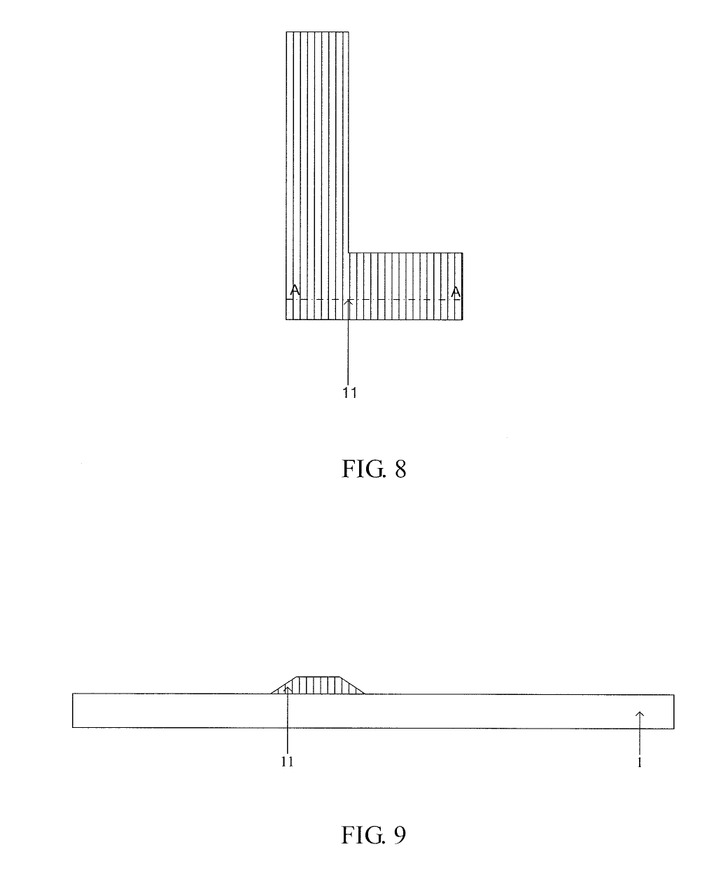

The second embodiment of the disclosed technology will be described with reference to FIGS. 8 to 17 below. In this embodiment, a method for fabricating a TFT array substrate integrated with color filters is provided, which can comprise the following steps.

Step 1. Firstly, a black matrix (BM) 11 is formed on a glass substrate 1 by a pattering process, and the plan view and the cross-sectional view of one pixel are shown in FIGS. 8 and 9 respectively.

In this embodiment, only the data lines, the source electrodes, the drain electrodes and the channel are shield by the black matrix shown in FIGS. 8 and 9. However, in the other embodiment of the disclosed technology, the gate lines may be also shielded by the black matrix.

For example, the black matrix can be made of a metal material, such as Cr, or an organic material. The material of the black matrix can be selected from the gate metal, SD metal and the like. The material of the black matrix can be a resin or photosensitive resin. In the case of photosensitive resin, only the processes of depositing, exposing and developing need to be performed, because the photosensitive resin has a photosensitive property as the photoresist.

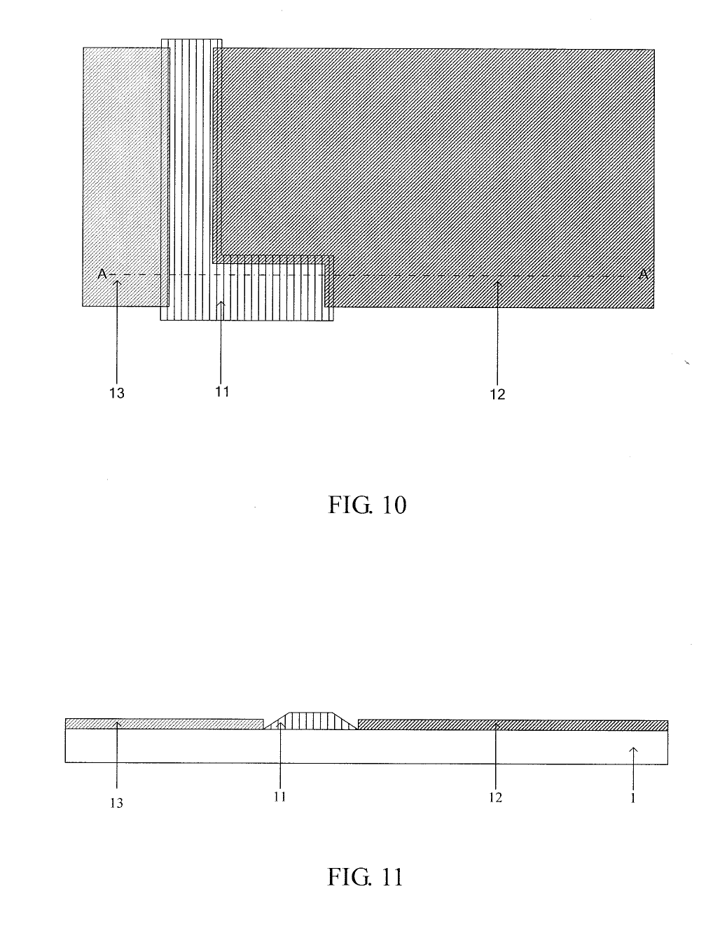

Step 2. On the glass substrate 1 obtained from the step 1, R filters 12, B filters (not shown) and G filters 13 are formed by three patterning processes respectively, and the plan view and the cross-sectional view of adjacent pixels are shown in FIGS. 10 and 11 respectively.

Optionally, the R filters 12, the B filters and the G filters 13 can be formed by using an ink-jetting, printing or the like method.

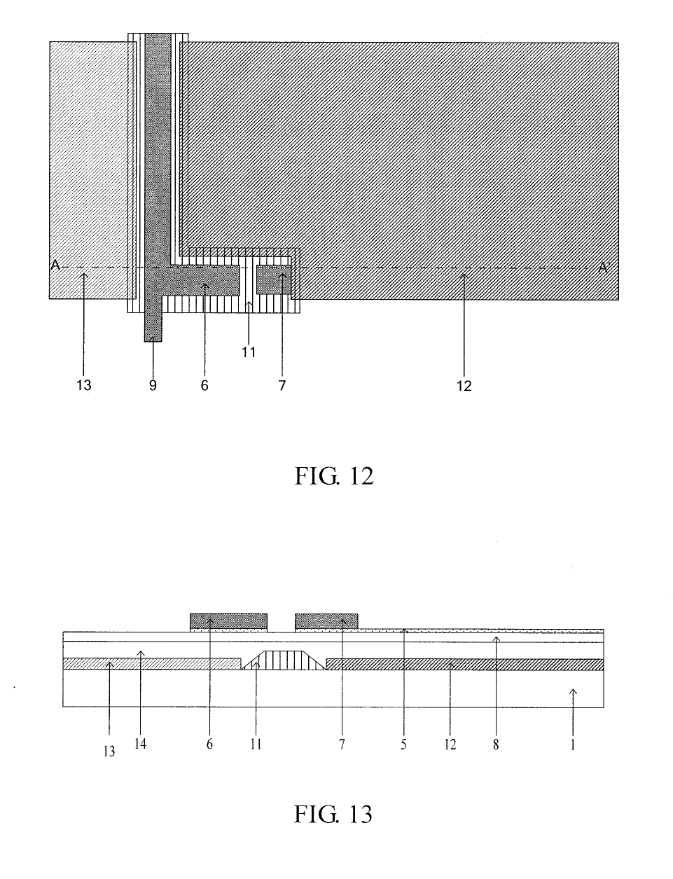

Step 3. On the glass substrate 1 obtained from the step 2, an organic flattening layer 14 with a thickness of 5000 to 25000 Å can be formed by a spin coating method. Then, a protective layer 8 is deposited on the organic flattening layer 14 with a thickness of 500 to 2000 Å by using a PECVD method. Next, a transparent conductive film with a thickness of about 300 to 1500 Å and a source-drain metal layer with a thickness of about 2000 to 3000 Å are sequentially deposited by using a sputtering or thermal evaporation method. After exposing with a gray tone or half tone mask, developing and several etching processes are performed, source electrodes 6, drain electrodes 7, data scan lines 9 and transparent pixel electrodes 5 are formed, and the plan view and the cross-sectional view of adjacent pixels are shown in FIGS. 12 and 13 respectively.

Generally, the transparent pixel electrodes 5 are made of ITO or the other metal and metal oxide. The source electrodes 6 and the drain electrodes 7 can be made of a material selected from a group consisting of Cr, W, Ti, Ta, Mo, Al, Cu and any alloy thereof, in a form of a single layer or multilayer structure.

For example, oxide, nitride or oxynitride can be selected to form the protective layer 8, and the corresponding reactive gas can be selected from a mixture of SiH₄, NH₃ and N₂ or a mixture of SiH₂Cl₂, NH₃ and N₂. Since the protective layer 8 is an inorganic insulating layer, it is possible to provide a better protect to the metal-oxide-semiconductor layer and improve the stability of the metal-oxide-semiconductor layer.

In an example, the protective layer is an inorganic insulating layer having better insulating property, such as silicon oxide and silicon nitride, or metal oxide insulating layer, such as Al₂O₃.

Here, the organic flattening layer 14 can flatten the surface of the glass substrate 1 and serve as an insulating layer as well.

In this step, before depositing the transparent pixel electrode, the protective layer can be deposited on the glass substrate in advance. The protective layer can protect the TFT channel to prevent the TFT channel from contacting with the glass substrate directly and giving rise to a poor interface.

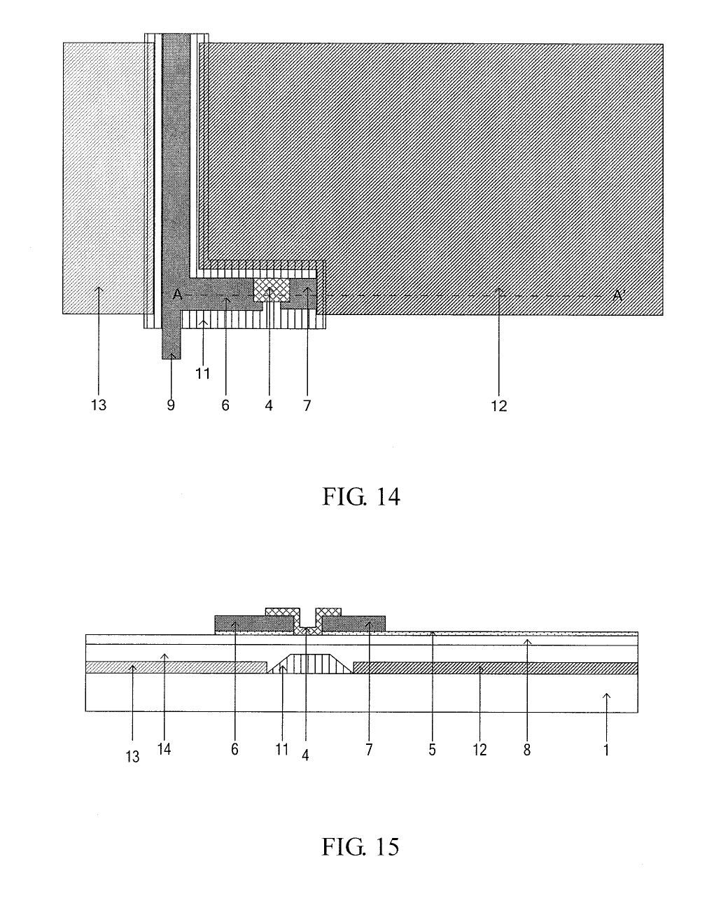

Step 4. On the substrate obtained from the step 3, a semiconductor layer with a thickness of about 100 to 4000 Å is deposited. Then, a patterned semiconductor layer 4 is formed by a patterning process, and the plan view and the cross-sectional view of adjacent pixels are shown in FIGS. 14 and 15 respectively.

For example, the semiconductor layer 4 can be made of amorphous IGZO or the other metal oxide semiconductor materials.

In this step, since the semiconductor layer can be made of a semiconductor material of metal oxide, such as IGZO, having a wide gap, which leads to substantially no light leakage current generated when the semiconductor layer is irradiated by any visible light. Therefore, there is no need to use a light-shielding layer in the later fabricating process, which facilitates to simplify the fabricating process and reduce the cost.

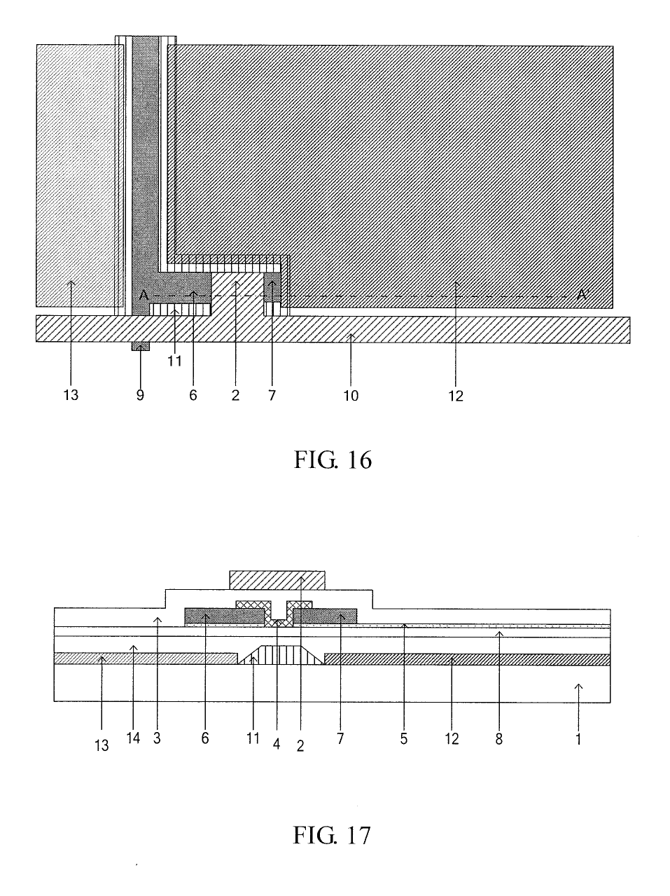

Step 5. On the substrate obtained from the step 4, a gate insulator 3 with a thickness of 1000 to 4000 Å is deposited successively by using PECVD, then a gate metal film with a thickness of 4000 to 15000 Å is deposited, and finally gate electrodes 2 and gate scan lines 10 are formed by a patterning process. So far the fabricating of the TFT array substrate is completed, and the plan view and the cross-sectional view of adjacent pixels are shown in FIGS. 16 and 17 respectively.

For example, oxide, nitride or oxide nitride can be selected to form the gate insulator 3, and the corresponding reactive gas can be selected from a mixture of SiH₄, NH₃ and N₂ or a mixture of SiH₂Cl₂, NH₃ and N₂. The gate metal film can be made of a material selected from a group consisting of Cr, W, Cu, Ti, Ta, Mo and any alloy thereof, in a form of a single layer or multilayer structure.

Here, the gate insulator 3 can be in a form of a single layer or dual layer structure. When the gate insulator 3 comprises two sub-layers, one of the sub-layers which contacts the semiconductor layer is deposited at a lower speed than that of the other sub-layer. In this manner, it is possible to form a better interface between the gate insulator 3 and the semiconductor layer, which facilities to improve properties of the TFT and improve the production efficiency.

In this embodiment, the gate metal film can be made of a material selected from a group consisting of Cr, W, Cu, Ti, Ta, Mo and any alloy thereof. Alternatively, the gate metal film can be made of a gate metal layer consisting of two or more metal layers.

In this embodiment, the red filters, the green filters and the blue filters are formed directly on the TFT array substrate by pattering processes. Since the precise of the patterning process is on the order of 5 μm, much higher than that of the bonding process (on the order of 3 mm), the aperture ratio of LCD can be increased significantly. Furthermore, it is possible to prevent the semiconductor layer from being damaged in forming the source and the drain electrodes by firstly forming the source and the drain electrodes and then forming the semiconductor layer on the base substrate.

It should be appreciated that the embodiments described above are intended to illustrate but not limit the present disclosed technology. Although the present disclosed technology has been described in detail herein with reference to the preferred embodiments, it should be understood by those skilled in the art that the present disclosed technology can be modified and some of the technical features can be equivalently substituted without departing from the spirit and scope of the present disclosed technology.

What is claimed is:

1. A method for fabricating a thin film transistor (TFT) array substrate, comprising the steps of:
(1) depositing a transparent conductive film layer and a source-drain metal layer in this order on a base substrate, and forming source electrodes, drain electrodes, data scan lines and transparent pixel electrodes by a first pattering process, with the transparent conductive film layer being left under the source electrodes, the drain electrodes and the data scan lines;
(2) on the substrate obtained from the step (1), depositing a semiconductor layer and forming a patterned semiconductor layer by a second pattering process; and
(3) on the substrate obtained from the step (2), depositing a gate insulator and a gate metal film in this order, and forming gate electrodes and gate scan lines by a third pattering process, the gate electrodes being located over the patterned semiconductor layer.

2. The method for fabricating the TFT array substrate according to claim 1, wherein before depositing the transparent conductive film layer and the source-drain metal layer on the base substrate, the method further comprises:
forming a protective layer on the base substrate.

3. The method for fabricating the TFT array substrate according to claim 1, wherein before depositing the transparent conductive film layer and the source-drain metal layer on the base substrate, the method further comprises:
forming a black matrix and forming a variety of color filters on the base substrate.

4. The method for fabricating the TFT array substrate according to claim 3, wherein after forming the black matrix and forming the variety of color filters on the base substrate, and before depositing the transparent conductive film layer and the source-drain metal layer on the base substrate, the method further comprises:
forming an organic flattening layer on the base substrate, and then forming a protective layer on the organic flattening layer.

5. The method for fabricating the TFT array substrate according to claim 1, wherein the depositing the gate insulator comprises:
depositing two gate insulating sub-layers successively by using a plasma enhanced chemical vapor deposition (PECVD) method, wherein one of the sub-layers which contacts the semiconductor layer is deposited at a lower speed than that of the other sub-layer.

6. The method for fabricating the TFT array substrate according to claim 2, wherein the depositing the gate insulator comprises:
depositing two gate insulating sub-layers successively by using a plasma enhanced chemical vapor deposition (PECVD) process, wherein one of the sub-layers which contacts the semiconductor layer is deposited at a lower speed than that of the other sub-layer.

7. The method for fabricating the TFT array substrate according to claim 3, wherein the depositing the gate insulator comprises:
depositing two gate insulating sub-layers successively by using a plasma enhanced chemical vapor deposition (PECVD) process, wherein one of the sub-layers which contacts the semiconductor layer is deposited at a lower speed than that of the other sub-layer.

8. The method for fabricating the TFT array substrate according to claim 4, wherein the depositing the gate insulator comprises:
depositing two gate insulating sub-layers successively by using a plasma enhanced chemical vapor deposition (PECVD) process, wherein one of the sub-layers which contacts the semiconductor layer is deposited at a lower speed than that of the other sub-layer.

9. The method for fabricating the TFT array substrate according to claim 1, wherein the forming of the source electrodes, the drain electrodes, the data scan lines and the transparent pixel electrodes by the first pattering process comprises:
forming the source electrodes, the drain electrodes, the data scan lines and the transparent pixel electrodes by exposing with a gray tone or half tone mask, developing and several etching processes.

10. The method for fabricating the TFT array substrate according to claim 2, wherein the forming of the source electrodes, the drain electrodes, the data scan lines and the transparent pixel electrodes by the first pattering process comprises:
forming the source electrodes, the drain electrodes, the data scan lines and the transparent pixel electrodes by exposing with a gray tone or half tone mask, developing and several etching processes.

11. The method for fabricating the TFT array substrate according to claim 3, wherein the forming of the source electrodes, the drain electrodes, the data scan lines and the transparent pixel electrodes by the first pattering process comprises:
forming the source electrodes, the drain electrodes, the data scan lines and the transparent pixel electrodes by exposing with a gray tone or half tone mask, developing and several etching processes.

12. The method for fabricating the TFT array substrate according to claim 4, wherein the forming of the source electrodes, the drain electrodes, the data scan lines and the transparent pixel electrodes by the first pattering process comprises:
forming the source electrodes, the drain electrodes, the data scan lines and the transparent pixel electrodes by exposing with a gray tone or half tone mask, developing and several etching processes.

13. A thin film transistor (TFT) array substrate comprising:
a base substrate;
transparent pixel electrodes provided above the base substrate;
source electrodes, drain electrodes and data scan lines with the transparent conductive film for forming the transparent pixel electrodes being left under them;
a patterned semiconductor layer formed on the source electrodes and the drain electrodes;
a gate insulator covering the patterned semiconductor layer; and
gate electrodes and gate scan lines formed on the gate insulator and located over the patterned semiconductor layer.

14. The TFT array substrate according to claim 13, wherein the array substrate further comprises a protective layer formed on the array substrate, and the transparent pixel electrodes are formed on the protective layer.

15. The TFT array substrate according to claim 13, wherein the array substrate further comprises a black matrix and a variety of color filters, both of which are formed on the array substrate, and the transparent pixel electrodes are formed on the black matrix and the color filters.

16. The TFT array substrate according to claim 15, wherein the array substrate further comprises an organic flattening layer and a protective layer, both of which are formed on the black matrix and the color filters, and the organic flattening layer is provided on the base substrate, and the protective layer is deposited on the organic flatting layer.
